(19) United States
(12) Patent Application Publication
(10) Pub. No.: US 2025/0314713 A1
(43) Pub. Date: Oct. 9, 2025

(54) POWER SUPPLY SYSTEM AND METHOD FOR MONITORING AGING LEVEL OF POWER SUPPLY SYSTEM

(71) Applicant: Delta Electronics (Thailand) Public Company Limited, Samutprakarn (TH)

(72) Inventors: Phichej Cheevanantachai, Samutprakarn (TH); Montree Wichittanakom, Samutprakarn (TH); Pannaphat Sribang, Samutprakarn (TH); Weerapus Pakakasama, Samutprakarn (TH)

(21) Appl. No.: 19/097,538

(22) Filed: Apr. 1, 2025

Related U.S. Application Data
(60) Provisional application No. 63/573,650, filed on Apr. 3, 2024.

(51) Int. Cl. G01R 31/40; G01R 19/165; H02M 1/00; H02M 1/42; H02M 1/44

(52) U.S. Cl. CPC G01R 31/40; G01R 19/16538; H02M 1/007; H02M 1/42; H02M 1/44

(57) ABSTRACT

A power supply system and a method for monitoring aging level of power supply system are provided. The method includes steps of: (a) providing the power supply system including a first conversion circuit, a second conversion circuit and a control circuit; (b) converting a secondary electrical parameter of the second conversion circuit into a PWM signal by a secondary control unit; (c) transmitting the PWM signal from the secondary control unit to a primary control unit through the digital opto-isolation coupler; (d) obtaining an aging reference parameter according to the secondary electrical parameter, reflected by the PMW signal, and a primary electrical parameter of the first conversion circuit by the primary control unit; and (e) comparing the aging reference parameter with a parameter threshold to determine the aging level of the power supply system by the primary control unit.

### CROSS-REFERENCE TO RELATED APPLICATION

This application claims the benefit of U.S. Provisional Application No. 63/573,650 filed on Apr. 3, 2024 and entitled “MULTI-DIGIT MODULATION CODING TECHNIQUE USING SINGLE OPTO-ISOLATOR AND ITS APPLICATION IN POWER MODULE REAL TIME MONITORING”. The entire contents of the above-mentioned patent application are incorporated herein by reference for all purposes.

### FIELD OF THE INVENTION

The present disclosure relates to a power supply system and a monitoring method thereof, and more particularly to a power supply system and a method for monitoring an aging level of the power supply system.

### BACKGROUND OF THE INVENTION

Generally, a conventional power supply system may include an AC/DC circuit and an isolated DC/DC circuit. To determine the aging level of the power supply system, it is necessary to obtain the electrical parameters of the AC/DC circuit (e.g., the input power of the AC/DC circuit) and the electrical parameters of the isolated DC/DC circuit (e.g., the output power of the isolated DC/DC circuit).

However, since the electrical parameters of the AC/DC circuit and the isolated DC/DC circuit may be located on the electrically isolated primary side and secondary side, respectively, it is difficult to obtain all required electrical parameters simultaneously on either the primary or secondary side to determine real-time status of the power supply system. Although conventional methods allow data transmission based on the UART (Universal Asynchronous Receiver-Transmitter) communication protocol to transfer the electrical parameter of the AC/DC circuit from the primary side to the secondary side, or to transfer the electrical parameter of the isolated DC/DC circuit from the secondary side to the primary side, the transmission delay affects the timeliness of the information, making it challenging to use the transmitted data for real-time system status calculation.

Therefore, there is a need of providing a power supply system and a method for monitoring an aging level of the power supply system in order to overcome the drawbacks of the conventional technologies.

### SUMMARY OF THE INVENTION

The present disclosure provides a power supply system and a method for monitoring an aging level of the power supply system. According to the said power supply system and method, the aging level of the power supply system is continuously monitored during the operation of the power supply system.

In accordance with an aspect of the present disclosure, a method for monitoring an aging level of a power supply system is provided. The method includes steps of: (a) providing the power supply system, wherein the power supply system includes a first conversion circuit, a second conversion circuit and a control circuit, the first conversion circuit is electrically connected to the second conversion circuit, the control circuit includes a primary control unit, a secondary control unit and a digital opto-isolation coupler, the primary control unit is electrically connected to the first conversion circuit and is isolated from the secondary control unit, and the digital opto-isolation coupler is configured to provide signal transmission between the primary control unit and the secondary control unit with electrical isolation; (b) converting a secondary electrical parameter of the second conversion circuit into a PWM (pulse width modulation) signal by the secondary control unit; (c) transmitting the PWM signal from the secondary control unit to the primary control unit through the digital opto-isolation coupler; (d) obtaining an aging reference parameter according to the secondary electrical parameter, reflected by the PMW signal, and a primary electrical parameter of the first conversion circuit by the primary control unit; and (e) comparing the aging reference parameter with a parameter threshold to determine the aging level of the power supply system by the primary control unit.

In accordance with an aspect of the present disclosure, a power supply system is provided. The power supply system includes a first conversion circuit, a second conversion circuit and a control circuit. The second conversion circuit is electrically connected to the first conversion circuit. The control circuit includes a primary control unit, a secondary control unit and a digital opto-isolation coupler. The primary control unit is electrically connected to the first conversion circuit. The secondary control unit is electrically connected to an output of the second conversion circuit, and is configured to convert a secondary electrical parameter of the second conversion circuit into a PWM signal. The secondary control unit is isolated from the primary control unit. The digital opto-isolation coupler is configured to provide signal transmission between the primary control unit and the secondary control unit with electrical isolation. The digital opto-isolation coupler is configured to transmit the PWM signal from the secondary control unit to the primary control unit, the primary control unit is configured to obtain an aging reference parameter according to the secondary electrical parameter, reflected by the PWM signal, and a primary electrical parameter of the first conversion circuit, and the primary control unit is further configured to compare the aging reference parameter with a parameter threshold to determine an aging level of the power supply system.

The above contents of the present disclosure will become more readily apparent to those ordinarily skilled in the art after reviewing the following detailed description and accompanying drawings, in which:

### BRIEF DESCRIPTION OF THE DRAWINGS

FIG. 1 is a schematic block diagram illustrating a power supply system according to an embodiment of the present disclosure;

FIG. 2 is a schematic flow chart illustrating a method for monitoring an aging level of the power supply system according to an embodiment of the present disclosure;

FIG. 3 is a schematic flow chart illustrating a variant of the method for monitoring an aging level of the power supply system of FIG. 2

FIG. 4 schematically shows the efficiency threshold determined according to the efficiency data of good units and RMA units;

FIG. 5 schematically shows the efficiency warning level set according to the efficiency threshold of FIG. 4;

FIG. 6 is a schematic flow chart illustrating substeps of the step ST6 of the method for monitoring the aging level of the power supply system shown in FIG. 3 according to an embodiment of the present disclosure;

FIG. 7 is a schematic block diagram illustrating an implementation of the power supply system of FIG. 1;

FIG. 8 schematically shows an implementation of the digital opto-isolation coupler of the present disclosure;

FIG. 9 is a schematic flow chart illustrating a variant of the method for monitoring an aging level of the power supply system of FIG. 2; and

FIG. 10 schematically shows the relation between the ripple voltage threshold and the output power of the second conversion circuit under different operating scenarios.

### DETAILED DESCRIPTION OF THE PREFERRED EMBODIMENT

The present disclosure will now be described more specifically with reference to the following embodiments. It is to be noted that the following descriptions of preferred embodiments of this disclosure are presented herein for purpose of illustration and description only. It is not intended to be exhaustive or to be limited to the precise form disclosed.

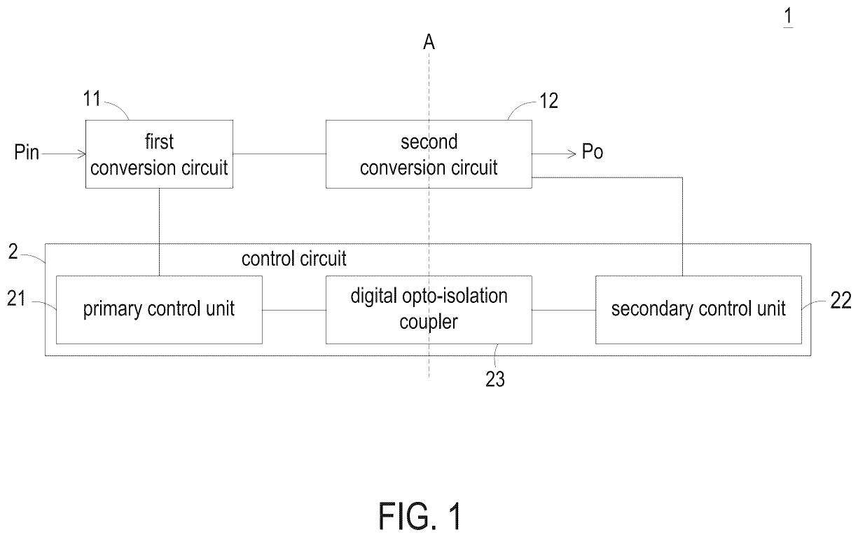

Please refer to FIG. 1. FIG. 1 is a schematic block diagram illustrating a power supply system according to an embodiment of the present disclosure. In FIG. 1, the line A is used to separate a primary side and a secondary side isolated with each other. Specifically, the left side of line A is the primary side, and the right side of line A is the secondary side. As shown in FIG. 1, the power supply system 1 includes a first conversion circuit 11, a second conversion circuit 12 and a control circuit 2. The first conversion circuit 11 is located at the primary side, and is configured to receive an input power Pin and convert the input power Pin into a DC power. The input power Pin may be an AC power or a DC power, and corresponding, the first conversion circuit 11 may be an AC/DC circuit or a DC/DC circuit. The second conversion circuit 12 is connected to the first conversion circuit 11, and is configured to receive the DC power from the first conversion circuit 11 and convert the DC power into an output power Po. The first conversion circuit 11 and the second conversion circuit 12 are applied with isolated voltage reference system, for example, an isolated grounding system. In specific, the second conversion circuit 12 includes a primary part located at the primary side and a secondary part located at the secondary side, and the primary part of the second conversion circuit 12 is connected to the first conversion circuit 11. For instance, the second conversion circuit 12 may be an isolated DC/DC circuit including an isolated transformer which is configured to transfer power between the primary and secondary parts of the second conversion circuit 12. The input power Pin received by the first conversion circuit 11 and the output power Po provided by the second conversion circuit 12 are regarded as the input power and output power of the power supply system 1 respectively.

The control circuit 2 includes a primary control unit 21 and a secondary control unit 22. The primary control unit 21 is electrically connected to the first conversion circuit 11 and is located at the primary side. The secondary control unit 22 is located at the secondary side and is isolated from the primary control unit 21. Further, the secondary control unit 22 is electrically connected to an output side of the second conversion circuit 12. For example, the primary control unit 21 and the secondary control unit 22 may be implemented by microcontroller units or microprocessor units, but not limited thereto. The control circuit 2 may further includes a digital opto-isolation coupler 23 according to the isolated voltage reference system. The digital opto-isolation coupler 23 is configured to provide signal transmission between the primary control unit 21 and the secondary control unit 22 with electrical isolation. In an embodiment, the digital opto-isolation coupler 23 may include a plurality of opto-isolators, each of which includes a pair of input and output ports, and each digital signal (PWM, pulse width modulation, signal) is transmitted by one of the plurality of opto-isolators. For example, the opto-isolator may include a light-emitting diode and a photo detector with electrical isolation, but not exclusively.

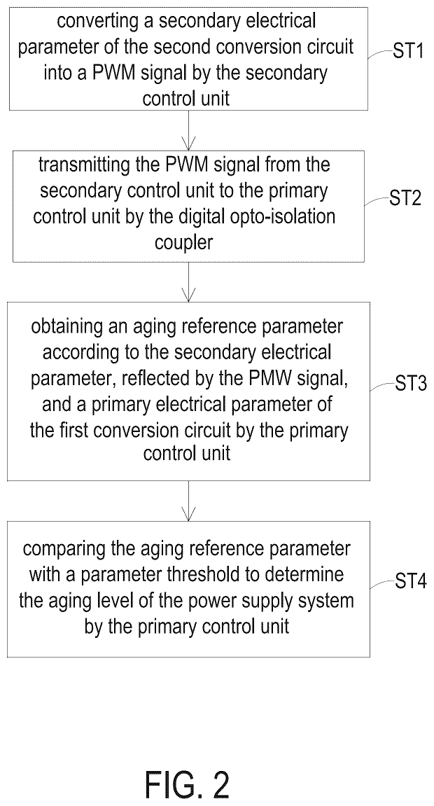

Please refer to FIG. 2 in conjunction with FIG. 1. FIG. 2 is a schematic flow chart illustrating a method for monitoring an aging level of the power supply system 1 according to an embodiment of the present disclosure. Firstly, in step ST1, the secondary control unit 22 converts a secondary electrical parameter of the second conversion circuit 12 into a PWM signal. The specific way of sampling the secondary electrical parameter is not limited in the present disclosure. For example, the secondary electrical parameter may be sampled by an external sampling circuit and provided to the secondary control unit 22, or the secondary electrical parameter may be sampled by a sampling circuit of the control circuit 2 at the secondary side. The secondary electrical parameter is for example but not limited to include the output current Io, output voltage Vo and output power Po of the second conversion circuit 12. Then, in step ST2, the digital opto-isolation coupler 23 transmits the PWM signal from the secondary control unit 22 to the primary control unit 21. Afterwards, in step ST3, the primary control unit 21 obtains an aging reference parameter according to the secondary electrical parameter, reflected by the PMW signal, and a primary electrical parameter of the first conversion circuit 11. The specific way of sampling the primary electrical parameter is not limited in the present disclosure. For example, the primary electrical parameter may be sampled by an external sampling circuit and provided to the primary control unit 21, or the primary electrical parameter may be sampled by a sampling circuit of the control circuit 2 at the primary side. The primary electrical parameter is for example but not limited to include the input current Iin, input voltage Vin and input power Pin of the first conversion circuit 11. Finally, in step ST4, the primary control unit 21 compares the aging reference parameter with a parameter threshold to determine the aging level of the power supply system 1. Accordingly, based on the signal transmission through the digital opto-isolation coupler 23 from the secondary side to the primary side of the power supply system 1, the real-time status of the power supply system 1 can be obtained and used to monitor the aging level of the power supply system 1 by the primary control unit 21 at the primary side.

In addition, in an embodiment, the secondary control unit 22 may provide the PWM signal with different frequencies, different duty cycles, or different combinations of frequency and duty cycle to represent the secondary electrical parameter with different values. Correspondingly, the primary control unit 21 obtains the secondary electrical parameter reflected by the PWM signal according to the frequency and duty cycle of the PWM signal. For example, in the case that the secondary electrical parameter includes the output power Po, the PWM signal is provided with the duty cycle of 0, 0.25, 0.5, 0.75 or 1 when the output power Po is at 0, 25%, 50%, 75% or 100% of the rated load, respectively.

Moreover, in an embodiment, the secondary electrical parameter may include multi-bit information (e.g., including the output current Io and output voltage Vo). Correspondingly, the secondary control unit 22 may provide the PWM signal with different frequencies, different duty cycles, or different combinations of frequency and duty cycle to represent the multi-bit information, and the primary control unit 21 obtains the multi-bit information reflected by the PWM signal according to the frequency and duty cycle of the PWM signal.

For example, the secondary electrical parameter may include multiple parameter signals. In order to combine information of multiple parameter signals into a single PWM signal, each parameter signal is digitized into one-bit representation. For each parameter signal, the bit value 0 indicates a first status of the parameter signal, and the bit value 1 indicates a second status of the parameter signal. Depending on the number of the parameter signals, the number, or say length, of bits to be encoded into a single PWM signal is accordingly set. Coding or modulation of the multiple bits are performed by adjusting frequency and/or duty cycle of the PWM signal. For example, in the implementation of using only frequency modulation, different bit value combinations may correspond to different frequency values of the PWM signal, and the duty cycle of the PWM signal may be fixed. Taking the example of 2-bit modulation, the binary value is formed by two bits, each indicating the status of the corresponding parameter signal. Binary value of 00 corresponds to frequency F1, binary value of 01 corresponds to frequency F2, binary value of 10 corresponds to frequency F3 and binary value of 11 corresponds to frequency F4. The frequency values F1 to F4 may be determined by predefined rules, for example in ascending order by a fixed offset, such as from 1 kHz to 4 kHz with an offset of 1 kHz.

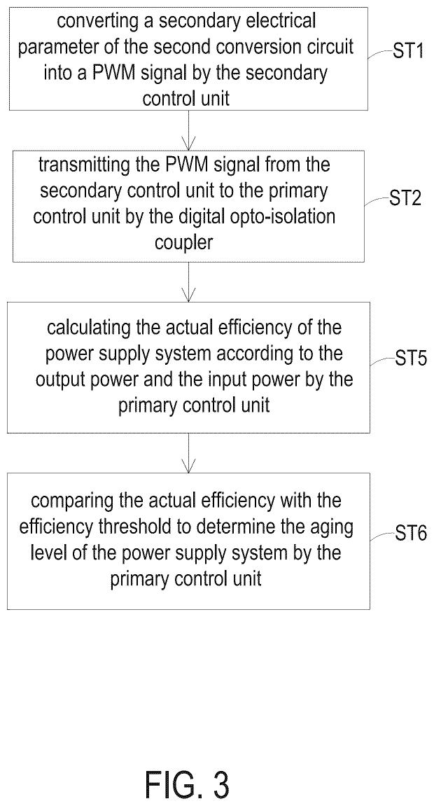

Please refer to FIG. 3 in conjunction with FIG. 1. FIG. 3 is a schematic flow chart illustrating a variant of the method for monitoring an aging level of the power supply system 1 of FIG. 2. In FIG. 3, the steps corresponding to those of FIG. 2 are designated by the same numeral references, and thus detailed descriptions thereof are omitted herein. Regarding the secondary electrical parameter obtained by the secondary control unit 22, in an embodiment, the secondary electrical parameter may include the output power Po. In another embodiment, the secondary electrical parameter may include the output current Io, and the output voltage Vo is constant. Under this circumstance, the primary control unit 21 calculates the output power Po according to the output voltage Vo and the output current Io included by the secondary electrical parameter. In addition, in this embodiment, the primary electrical parameter includes the input power Pin, the aging reference parameter includes an actual efficiency of the power supply system 1, and the parameter threshold includes an efficiency threshold. As shown in FIG. 3, in step ST5, the primary control unit 21 calculates the actual efficiency of the power supply system 1 according to the output power Po of the second conversion circuit 12 and the input power Pin of the first conversion circuit 11. Accordingly, based on the signal transmission through the digital opto-isolation coupler 23 from the secondary side to the primary side of the power supply system 1, the real-time system efficiency is obtained by the primary control unit 21 at the primary side. In an embodiment, the primary control unit 21 obtains the input power Pin of the first conversion circuit 11 according to the input voltage Vin and the input current Iin of the first conversion circuit 11, which may be sampled by an external sampling circuit or a sampling circuit of the control circuit 2 at the primary side. In step ST6, the primary control unit 21 compares the actual efficiency with the efficiency threshold to determine the aging level of the power supply system 1. In specific, the aging of the power supply system 1 (e.g., the aging or failure of the components of the power supply system 1) would cause a decrease in the efficiency of the power supply system 1. Accordingly, the actual efficiency can be used to determine the aging level of the power supply system 1. For example, if the actual efficiency is less than the efficiency threshold, the primary control unit 21 determines that the power supply system 1 has aged or has a fault of a component; and if the actual efficiency is greater than or equal to the efficiency threshold, the primary control unit 21 determines that the power supply system 1 has not aged. In addition, in an embodiment, the efficiency of the power supply system may be reflected by the power factor, thus the primary control unit 21 may also use the output power Po reflected by the PWM signal to check the power factor by comparing with an efficiency threshold.

Consequently, in the present disclosure, the aging level of the power supply system 1 can be continuously monitored based on real-time system efficiency during the operation of the power supply system 1.

In an embodiment, the primary control unit 21 calculates the actual efficiency of the power supply system 1 according to the input power Pin, the output power Po and auxiliary power of the power supply system 1. For example, the primary control unit 21 calculates the actual efficiency of the power supply system 1 by dividing a sum of the output power Po and the auxiliary power by the input power Pin. The auxiliary power is generated by the power supply system 1 based on the input power Pin, and is used to supply power to the internal components of the power supply system 1, such as fans.

In addition, in an embodiment, the secondary control unit 22 may provide the PWM signal with different frequencies, different duty cycles, or different combinations of frequency and duty cycle to represent the output power Po within different ranges or at different percentages of maximum power. Correspondingly, the primary control unit 21 zobtains the output power Po reflected by the PWM signal according to the frequency and duty cycle of the PWM signal. For example, the PWM signal is provided with the duty cycle of 0, 0.25, 0.5, 0.75 or 1 when the output power Po is at 0, 25%, 50%, 75% or 100% of the rated load, respectively.

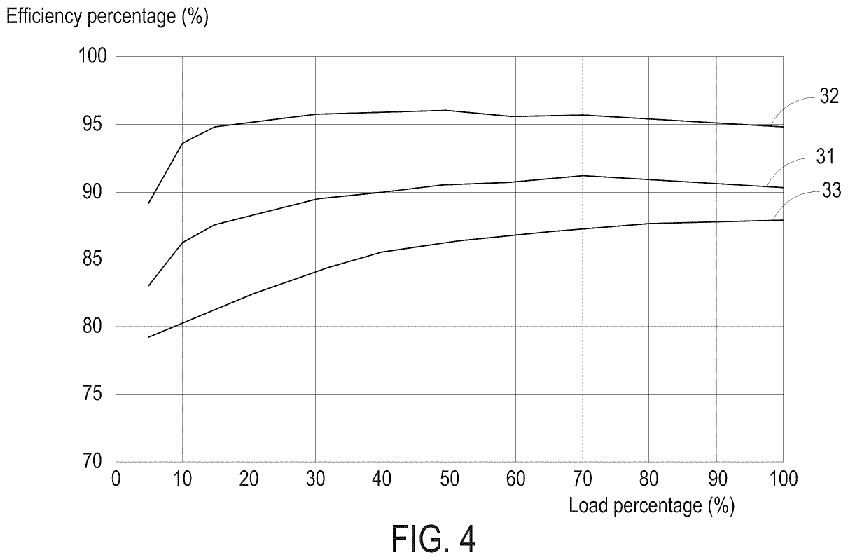

Moreover, the efficiency threshold is for example but not limited to be determined according to efficiency data of good units and RMA (return material authorization) units. For example, FIG. 4 schematically shows the efficiency threshold determined according to the efficiency data of good units and RMA units. In FIG. 4, waveform 31 represents the efficiency threshold, waveform 32 represents the efficiency data of good units, and waveform 33 represents the efficiency data of RMA units. Further, the waveforms 31, 32 and 33 are shown with the efficiency percentage of a rated efficiency of the power supply system 1 versus the load percentage of a rated load of the power supply system 1.

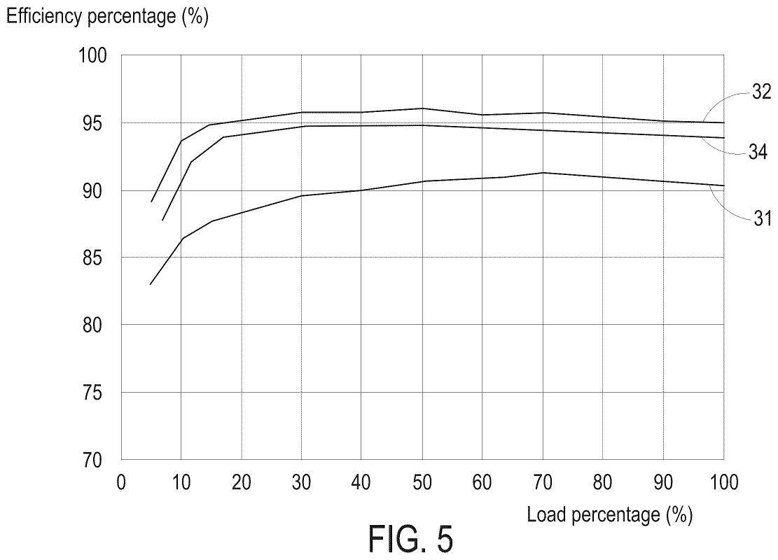

Furthermore, in an embodiment, to prevent hard failure damage because of over-aging of components and to cover the material tolerance, the primary control unit 21 may set one or more efficiency warning levels according to the efficiency threshold and determine the aging level of the power supply system 1 by comparing the actual efficiency with the one or more efficiency warning levels. For example, in an embodiment, as shown in FIG. 5, the primary control unit 21 may set an efficiency warning level (represented by waveform 34) according to the efficiency threshold. It can be observed that the efficiency warning level (waveform 34) is between the efficiency data of good units (waveform 32) and the efficiency threshold (waveform 31). The efficiency warning level may come from tolerance analysis of power supply system 1 by simulation or real test experiment to limit level, but not limited thereto. In an embodiment, the primary control unit 21 may set different efficiency warning levels. In addition, the efficiency of the power supply system 1 may be affected by the magnitude of output power Po. Therefore, in an embodiment, the primary control unit 21 may set different efficiency reference values based on the efficiency warning level (represented by waveform 34) corresponding to the output power Po with difference values. Correspondingly, the primary control unit 21 determines the aging level of the power supply system 1 by comparing the actual efficiency with the efficiency reference value corresponding to the output power Po. Consequently, through taking the affection of the output power Po on the efficiency into consideration, the accuracy of determining the aging level is improved.

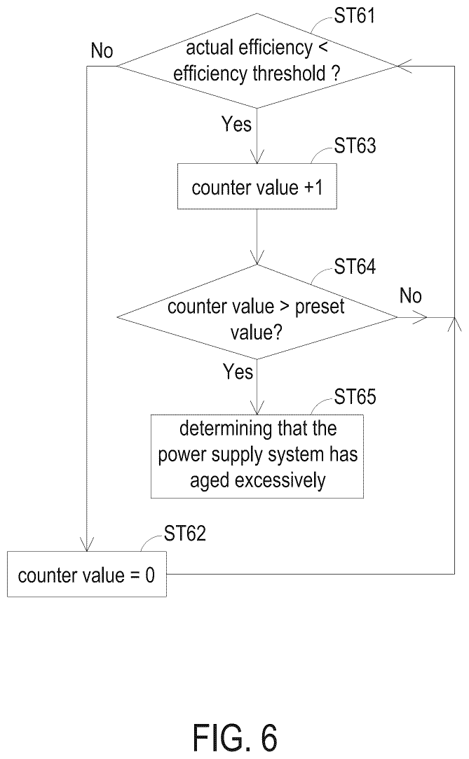

Please refer to FIG. 6 in conjunction with FIG. 1. FIG. 6 is a schematic flow chart illustrating substeps of the step ST6 of the method for monitoring the aging level of the power supply system shown in FIG. 3 according to an embodiment of the present disclosure. In an embodiment, the step of comparing the actual efficiency with the efficiency threshold to determine the aging level of the power supply system 1 includes the following substeps. Firstly, in substep ST61, the primary control unit 21 determines whether the actual efficiency is less than the efficiency threshold.

If the determination result of substep ST61 is negative, which means that the actual efficiency is greater than or equal to the efficiency threshold, substep ST62 is performed to reset a counter value of a counter in the primary control unit 21 to zero. After performing the substep ST62, the substep ST61 is performed again.

If the determination result of substep ST61 is positive, which means that the actual efficiency is less than the efficiency threshold, substep ST63 is performed to increase the counter value by one. After performing the substep ST63, substep ST64 is performed to determine whether the counter value is greater than a preset value. If the determination result of substep ST64 is negative, the substep ST61 is performed again. Conversely, if the determination result of substep ST64 is positive, the primary control unit 21 determines that the power supply system 1 has aged excessively (substep ST65), namely the aging level of the power supply system 1 exceeds a preset level (e.g., acceptable aging level).

In this embodiment, the counter value of the counter in the primary control unit 21 reflects the aging level of the power supply system 1. In specific, the larger the counter value is, the more seriously the power supply system 1 ages. Additionally, the preset value is used to determine whether the power supply system 1 has aged excessively and may be set according to actual requirements. In an embodiment, when the primary control unit 21 determines that the power supply system 1 has aged excessively (i.e., the counter value is greater than the preset value) the primary control unit 21 may issue an alert signal to warn the user. In addition, it is noted that when the efficiency warning level (as shown in FIG. 5) is set, the method of FIG. 6 may be modified to compare the efficiency warning level with the actual efficiency to determine the aging level of the power supply system 1.

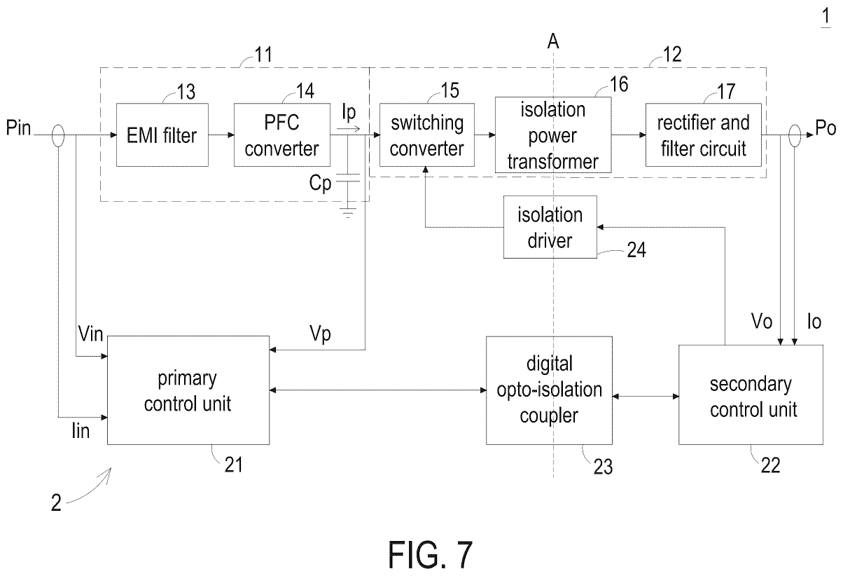

Please refer to FIG. 7. FIG. 7 is a schematic block diagram illustrating an implementation of the power supply system 1 of FIG. 1. The component parts and elements corresponding to those of FIG. 1 are designated by identical numeral references, and detailed descriptions thereof are omitted herein. As shown in FIG. 7, in the power supply system 1 of this embodiment, the first conversion circuit 11 is exemplified as an AC/DC conversion circuit and includes an EMI (electromagnetic interference) filter 13 and a PFC (power factor correction) circuit including a PFC converter 14 and a PFC output capacitor Cp. The second conversion circuit 12 includes a switching converter 15, an isolation power transformer 16 and a rectifier and filter circuit 17. The EMI filter 13 is configured to receive the input voltage Vin and perform EMI filtering. The PFC converter 14 is electrically connected to the EMI filter 13 and is configured to perform power factor correction and provide a PFC output voltage Vp (i.e., the voltage across the PFC output capacitor Cp) to the second conversion circuit 12. In the second conversion circuit 12, the switching converter 15 is located at the primary side, and the rectifier and filter circuit 17 is located at the secondary side. The switching converter 15 is electrically connected to the PFC converter 14 and is configured to receive and convert the PFC output voltage Vp into an AC voltage. The isolation power transformer 16 is electrically connected to the switching converter 15 and is configured to transmit the AC voltage from the primary side to the secondary side. The rectifier and filter circuit 17 is electrically connected to the isolation power transformer 16 and is configured to perform rectification and filtering on the AC voltage to generate the output voltage Vo of the second conversion circuit 12. In addition, in an embodiment, the control circuit 2 further includes an isolation driver 24. The isolation driver 24 is coupled between the secondary control unit 22 and the switching converter 15 of the second conversion circuit 12. The isolation driver 24 is configured to receive a control signal generated by the secondary control unit 22 and provide a driving signal for driving switches of the switching converter 15 according to the control signal. For example, the isolation stage of the isolation driver 24 may be implemented by opto-coupler, isolated transformer, capacitive isolation or magnetic isolation.

In addition to the signal transmission from the secondary control unit 22 to the primary control unit 21, the digital opto-isolation coupler 23 can also transmit the signal from the primary control unit 21 to the secondary control unit 22. For example, the primary control unit 21 may receive the operational parameter signals (e.g., the sensing signals of the input voltage Vin, input current lin and PFC output voltage Vp) of the first conversion circuit 11 at the primary side and convert them into digital signals, the digital signals are transmitted to the secondary control unit 22 through the digital opto-isolation coupler 23, and the secondary control unit 22 obtains the statuses of the operational parameter signals from the digital signals and controls the second conversion circuit 12 accordingly. In addition, in an embodiment, the digital opto-isolation coupler 23 is also used for data transmission between the primary control unit 21 and the secondary control unit 22 based on UART (Universal Asynchronous Receiver-Transmitter) communication protocol. In particular, the digital opto-isolation coupler 23 may transmit the data from the primary control unit 21 to the secondary control unit 22 and transmit the data from the secondary control unit 22 to the primary control unit 21. It is noted that the above-mentioned monitoring method is unable to be realized based on the data transmission since the data transmission based on UART communication protocol is not fast enough to transmit the information of output power Po in real-time.

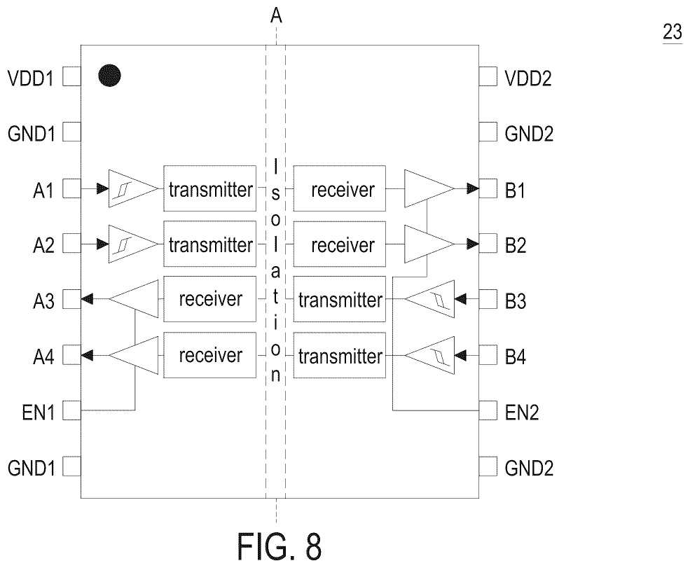

Please refer to FIG. 8. FIG. 8 schematically shows an implementation of the digital opto-isolation coupler 23 of the present disclosure. In FIG. 8, pins VDD1 and VDD2 are configured for power supply, pins GND1 and GND2 are configured for grounding, pins EN1 and EN2 are configured for enabling, and pins A1, A2, A3, A4, B1, B2, B3 and B4 are configured for digital input or output. In this embodiment, as shown in FIG. 8, the digital opto-isolation coupler 23 includes four opto-isolators, each including a transmitter and a receiver. The first opto-isolator includes the pin A1 at the primary side and the pin B1 at the secondary side, and the pins A1 and B1 serve as input and output pins respectively. The second opto-isolator includes the pin A2 at the primary side and the pin B2 at the secondary side, and the pins A2 and B2 serve as input and output pins respectively. The third opto-isolator includes the pin A3 at the primary side and the pin B3 at the secondary side, and the pins B3 and A3 serve as input and output pins respectively. The fourth opto-isolator includes the pin A4 at the primary side and the pin B4 at the secondary side, and the pins B4 and A4 serve as input and output pins respectively.

For example, the first opto-isolator transmit transmits the digital signal corresponding to the operational parameter signal of the first conversion circuit 11 from the primary control unit 21 to the secondary control unit 22. The second opto-isolator transmits the communication data from the primary control unit 21 to the secondary control unit 22. The third opto-isolator transmits the PWM signal reflecting the output power Po of the second conversion circuit 12 from the secondary control unit 22 to the primary control unit 21. The fourth opto-isolator transmits the communication data from the secondary control unit 22 to the primary control unit 21.

As mentioned above, the aging level of the power supply system 1 can be continuously monitored based on real-time system efficiency during the operation of the power supply system 1. The aging of the power supply system 1 may be caused by the aging of one or more components within the power supply system 1, for example but not limited to X capacitor of EMI filter 13, switching components and PFC output capacitor Cp. Since the PFC output capacitor Cp usually plays an important role in the power supply system 1, the present disclosure further provides a method of monitoring the aging level of the PFC output capacitor Cp.

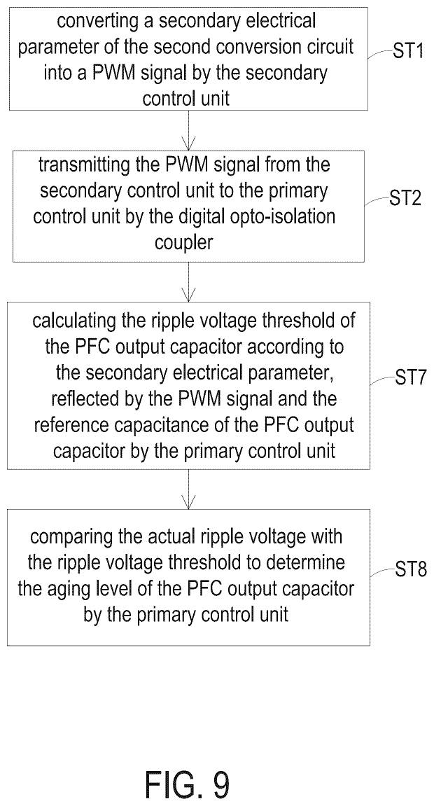

Please refer to FIG. 9 in conjunction with FIG. 7. FIG. 9 is a schematic flow chart illustrating a variant of the method for monitoring an aging level of the power supply system 1 of FIG. 2. Particularly, the method of FIG. 9 is for monitoring an aging level of the PFC output capacitor Cp of the power supply system 1. In FIG. 9, the steps corresponding to those of FIG. 2 are designated by the same numeral references, and thus detailed descriptions thereof are omitted herein. In this embodiment, the primary electrical parameter includes a reference capacitance of the PFC output capacitor Cp, the secondary electrical parameter includes the output power Po or output current Io of the second conversion circuit 12, the aging reference parameter includes the actual ripple voltage Vr of the PFC output capacitor Cp, and the parameter threshold includes a ripple voltage threshold Vth of the PFC output capacitor Cp. The reference capacitance of the PFC output capacitor Cp may be obtained from an aging-curve of the PFC output capacitor Cp, but not limited thereto. As shown in FIG. 9, in step ST7, the primary control unit 21 calculates the ripple voltage threshold Vth of the PFC output capacitor Cp according to the secondary electrical parameter, reflected by the PWM signal and the reference capacitance of the PFC output capacitor Cp. Therefore, the primary control unit 21 is capable of adjusting the ripple voltage threshold Vth correspondingly through calculation when the output power Po changes, to provide accurate protection settings for the PFC output capacitor Cp under various operation scenarios. In step ST8, the primary control unit 21 compares the actual ripple voltage Vr with the ripple voltage threshold Vth to determine the aging level of the PFC output capacitor Cp, which the actual ripple voltage Vr of PFC output capacitor Cp is continuously sampled for the primary control unit 21.

Consequently, in the present disclosure, the aging level of the PFC output capacitor Cp can be continuously monitored based on real-time load condition during the operation of the power supply system 1.

In an embodiment, in the power supply system 1 of FIG. 1, the ripple voltage threshold Vth of the PFC output capacitor Cp may be calculated as:

$$Vth = \frac{Ip}{2 * π * {f}_{line} * C ref} \qquad ( 1 )$$

In equation (1), Ip is the output current of the PFC converter 14, fₗᵢₙₑ is the line frequency of the AC input voltage Vin, and Cref is the reference capacitance of the PFC output capacitor Cp. fₗᵢₙₑ may be a line AC frequency, for example but not limited to is 50 Hz or 60 Hz, typically. Therefore, the primary control unit 21 obtains the output current Ip of the PFC converter based on or reflected by the secondary electrical parameter (i.e., the output current Io or the output power Po) reflected by the PWM signal, and calculates the ripple voltage threshold Vth according to the equation (1), which the output current Ip of the PFC converter 14 may be a function of output current Io of the second conversion circuit 12. Further, in an embodiment, the primary control unit 21 may set multiple threshold values based on the calculated ripple voltage threshold Vth under various operation scenarios, such as various load levels, for determining the more specific aging level of the PFC output capacitor Cp, and compare the actual ripple voltage Vr with the multiple threshold values. In addition, the acceptable tolerance may also be taken into consideration while determining the ripple voltage threshold Vth and the threshold values.

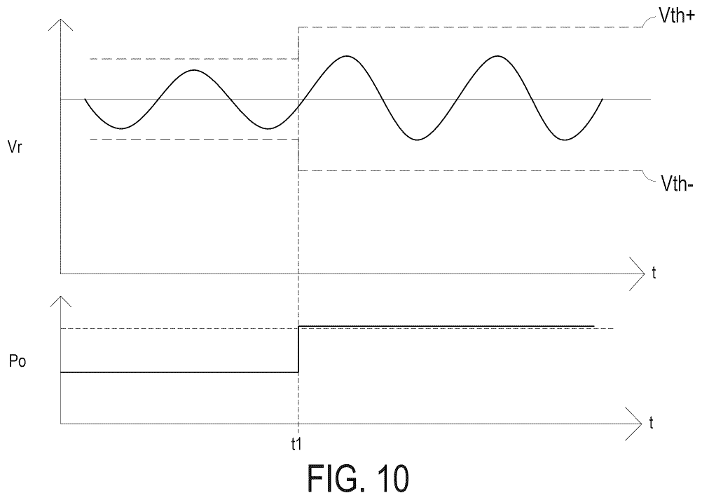

FIG. 10 schematically shows the relation between the ripple voltage threshold Vth and the output power Po of the second conversion circuit 12 under different operating scenarios. In FIG. 10, Vth+ and Vth− respectively represent the upper and lower limits of ripple voltage included by the ripple voltage threshold Vth and are depicted by dashed lines. As shown in FIG. 10, at time t1, the output power Po increases. Correspondingly, the upper limit of ripple voltage Vth+ increases, the lower limit of ripple voltage Vth− decreases, and thus the difference between the upper and lower limits of ripple voltage Vth+ and Vth−, named a peak-to-peak limit of ripple voltage, increases. For example, different operating scenarios may be represented by different output power Po, the output power Po may be 50% of the rated power corresponding to half-load before time t1, and the output power Po may be 100% of the rated power corresponding to full-load after time t1. Multiple thresholds for determining the aging of the capacitor can be set according to the output power Po. In this embodiment, the upper limit of ripple voltage Vth+ and the lower limit of ripple voltage Vth− can be set as different values corresponding to the half-load operation and full-load operation before and after time t1 respectively. The values of the upper and lower limits may be pre-determined or real-time determined in the primary control unit 21 by recognizing the output power Po which is sampled at the secondary side of the second conversion circuit 12 and transmitted by the PWM signal from the secondary control unit 22. It is determined that the PFC output capacitor Cp has aged when at least one of conditions is satisfied. The said conditions include that the peak value of the actual ripple voltage Vr is greater than the upper limit of ripple voltage Vth+, the valley value of the actual ripple voltage Vr is less than the lower limit of ripple voltage Vth−, and the peak-to-peak value of the actual ripple voltage Vr is greater than the difference between the upper limit of ripple voltage Vth+ and the lower limit of ripple voltage Vth− (i.e., the peak-to-peak limit). The form of the actual ripple voltage Vr is for example but not limited to the voltage of the PFC output capacitor Cp, or the ripple voltage which is obtained by subtracting the DC voltage from the voltage of the PFC output capacitor Cp.

While the disclosure has been described in terms of what is presently considered to be the most practical and preferred embodiments, it is to be understood that the disclosure needs not be limited to the disclosed embodiment. On the contrary, it is intended to cover various modifications and similar arrangements included within the spirit and scope of the appended claims which are to be accorded with the broadest interpretation so as to encompass all such modifications and similar structures.

What is claimed is:

1. A method for monitoring an aging level of a power supply system, comprising steps of:
(a) providing the power supply system, wherein the power supply system comprises a first conversion circuit, a second conversion circuit and a control circuit, the first conversion circuit is electrically connected to the second conversion circuit, the control circuit comprises a primary control unit, a secondary control unit and a digital opto-isolation coupler, the primary control unit is electrically connected to the first conversion circuit and is isolated from the secondary control unit, and the digital opto-isolation coupler is configured to provide signal transmission between the primary control unit and the secondary control unit with electrical isolation;
(b) converting a secondary electrical parameter of the second conversion circuit into a PWM (pulse width modulation) signal by the secondary control unit;
(c) transmitting the PWM signal from the secondary control unit to the primary control unit through the digital opto-isolation coupler;
(d) obtaining an aging reference parameter according to the secondary electrical parameter, reflected by the PMW signal, and a primary electrical parameter of the first conversion circuit by the primary control unit; and
(e) comparing the aging reference parameter with a parameter threshold to determine the aging level of the power supply system by the primary control unit.

2. The method according to claim 1, wherein in the step (b), the PWM signal is provided with different frequencies, different duty cycles, or different combinations of frequency and duty cycle to represent the secondary electrical parameter with difference values by the secondary control unit; and in the step (d), the secondary electrical parameter reflected by the PWM signal is obtained according to the frequency and the duty cycle of the PWM signal by the primary control unit.

3. The method according to claim 1, wherein the primary electrical parameter comprises an input power of the first conversion circuit, the secondary electrical parameter comprises an output power of the second conversion circuit or the primary control unit calculates the output power according to an output voltage of the second conversion circuit and an output current of the second conversion circuit comprised by the secondary electrical parameter, the aging reference parameter comprises an actual efficiency of the power supply system, and the parameter threshold comprises an efficiency threshold; wherein in the step (d), the actual efficiency is calculated according to the output power of the second conversion circuit and the input power of the first conversion circuit by the primary control unit; wherein in the step (e), the efficiency threshold is obtained by the primary control unit, and the actual efficiency is compared with the efficiency threshold to determine the aging level of the power supply system by the primary control unit.

4. The method according to claim 3, wherein the step (d) comprises utilizing the primary control unit to calculate the actual efficiency by dividing a sum of the output power and an auxiliary power of the power supply system by the input power, wherein the auxiliary power is generated by the power supply system based on the input power and is used to supply power to internal components of the power supply system.

5. The method according to claim 3, wherein the step (e) comprises:
setting one or more efficiency warning levels according to the efficiency threshold by the primary control unit; and
determining the aging level of the power supply system by comparing the actual efficiency with the one or more efficiency warning levels by the primary control unit.

6. The method according to claim 5, wherein the step (e) comprises:
based on each said efficiency warning level, setting efficiency reference values corresponding to the output power with difference values by the primary control unit; and
determining the aging level of the power supply system by comparing the actual efficiency with one of the efficiency reference values, corresponding to the output power, of each said efficiency warning level by the primary control unit.

7. The method according to claim 3, wherein the step (e) comprises substeps of:
(e1) determining whether the actual efficiency is less than the efficiency threshold by the primary control unit;
(e2) if a determination result of the substep (e1) is negative, resetting a counter value of a counter in the primary control unit to zero, and performing the substep (e1) again;
(e3) if the determination result of the substep (e1) is positive, increasing the counter value by one;
(e4) determining whether the counter value is greater than a preset value by the primary control unit;
(e5) if the determination result of the substep (e4) is negative, performing the substep (e1) again; and
(e6) if the determination result of the substep (e4) is positive, determining that the aging level of the power supply system exceeds a preset level by the primary control unit.

8. The method according to claim 7, further comprising a step of issuing an alert signal to warn a user by the primary control unit when the aging level of the power supply system exceeds the preset level.

9. The method according to claim 3, wherein the step (e) comprises:
if the actual efficiency is less than the efficiency threshold, determining that the power supply system has aged by the primary control unit; and
if the actual efficiency is greater than or equal to the efficiency threshold, determining that the power supply system has not aged by the primary control unit.

10. The method according to claim 1, wherein the digital opto-isolation coupler comprises a plurality of opto-isolators, each of which is configured to transmit one-bit signal, and in the step (c), the PWM signal from the secondary control unit is transmitted to the primary control unit through one of the plurality of opto-isolators.

11. The method according to claim 1, wherein the first conversion circuit comprises a PFC (power factor correction) circuit with a PFC output capacitor, the primary electrical parameter comprises a reference capacitance of the PFC output capacitor, the secondary electrical parameter comprises an output power or an output current of the second conversion circuit, the aging reference parameter comprises an actual ripple voltage of the PFC output capacitor, and the parameter threshold comprises a ripple voltage threshold of the PFC output capacitor; wherein in the step (e), the ripple voltage threshold is calculated according to the secondary electrical parameter and the reference capacitance by the primary control unit, the actual ripple voltage is obtained by the primary control unit, and the actual ripple voltage is compared with the ripple voltage threshold to determine an aging level of the PFC output capacitor of the power supply system by the primary control unit.

12. The method according to claim 11, wherein in the step (d), the ripple voltage threshold of the PFC output capacitor is calculated as:
$$Vth = \frac{Ip}{2 * π * {f}_{line} * C ref}$$
where Vth is the ripple voltage threshold, Ip is the output current of the PFC circuit obtained by the primary control unit according to the secondary electrical parameter, fₗᵢₙₑ is a line frequency, and Cref is the reference capacitance of the PFC output capacitor.

13. The method according to claim 11, further comprising steps of:
setting threshold values based on the ripple voltage threshold by the primary control unit; and
comparing the actual ripple voltage with the threshold values to determine the aging level of the PFC output capacitor by the primary control unit.

14. The method according to claim 11, further comprising a step of determining that the PFC output capacitor has aged when at least one of conditions is satisfied by the primary control unit, wherein the conditions comprises that a peak value of the actual ripple voltage is greater than an upper limit of the ripple voltage threshold, a valley value of the actual ripple voltage is less than a lower limit of the ripple voltage threshold, and a peak-to-peak value of the actual ripple voltage is greater than a peak-to-peak limit of the ripple voltage threshold.

15. The method according to claim 1, wherein the secondary electrical parameter comprises multi-bit information, and in the step (b), the PWM signal is provided with different frequencies, different duty cycles, or different combinations of frequency and duty cycle to represent the multi-bit information; and in the step (d), the multi-bit information of the secondary electrical parameter reflected by the PWM signal is obtained according to the frequency and the duty cycle of the PWM signal by the primary control unit.

16. A power supply system, comprising:
a first conversion circuit;
a second conversion circuit, electrically connected to the first conversion circuit; and
a control circuit, comprising:
a primary control unit, electrically connected to the first conversion circuit;
a secondary control unit, electrically connected to the second conversion circuit, and configured to convert a secondary electrical parameter of the second conversion circuit into a PWM signal, wherein the secondary control unit is isolated from the primary control unit; and
a digital opto-isolation coupler, configured to provide signal transmission between the primary control unit and the secondary control unit with electrical isolation,
wherein the digital opto-isolation coupler is configured to transmit the PWM signal from the secondary control unit to the primary control unit, the primary control unit is configured to obtain an aging reference parameter according to the secondary electrical parameter, reflected by the PWM signal, and a primary electrical parameter of the first conversion circuit, and the primary control unit is further configured to compare the aging reference parameter with a parameter threshold to determine an aging level of the power supply system.

17. The power supply system according to claim 16, wherein the secondary control unit is configured to provide the PWM signal with different frequencies, different duty cycles, or different combinations of frequency and duty cycle to represent the secondary electrical parameter with difference values, and the primary control unit is configured to obtain the secondary electrical parameter reflected by the PWM signal according to the frequency and the duty cycle of the PWM signal.

18. The power supply system according to claim 16, wherein the primary electrical parameter comprises an input power of the first conversion circuit, the secondary electrical parameter comprises an output power of the second conversion circuit or the primary control unit calculates the output power according to an output voltage of the second conversion circuit and an output current of the second conversion circuit comprised by the secondary electrical parameter, the aging reference parameter comprises an actual efficiency of the power supply system, and the parameter threshold comprises an efficiency threshold; wherein the primary control unit is configured to calculate the actual efficiency according to the output power of the second conversion circuit and the input power of the first conversion circuit, obtain the efficiency threshold, and compare the actual efficiency with the efficiency threshold to determine the aging level of the power supply system.

19. The power supply system according to claim 18, wherein the primary control unit is configured to calculate the actual efficiency by dividing a sum of the output power and an auxiliary power of the power supply system by the input power, and the auxiliary power is generated by the power supply system based on the input power and is used to supply power to internal components of the power supply system.

20. The power supply system according to claim 18, wherein the primary control unit is configured to:
set one or more efficiency warning levels according to the efficiency threshold; and
determine the aging level of the power supply system by comparing the actual efficiency with the one or more efficiency warning levels.

21. The power supply system according to claim 20, wherein the primary control unit is configured to:
based on each said efficiency warning level, set efficiency reference values corresponding to the output power with difference values; and
determine the aging level of the power supply system by comparing the actual efficiency with one of the efficiency reference values, corresponding to the output power, of each said efficiency warning level.

22. The power supply system according to claim 18, wherein the primary control unit is configured to:
determine whether the actual efficiency is less than the efficiency threshold;
if the actual efficiency is greater than or equal to the efficiency threshold, reset a counter value of a counter in the primary control unit to zero, and determine whether the actual efficiency is less than the efficiency threshold again;
if the actual efficiency is less than the efficiency threshold, increase the counter value by one;
determine whether the counter value is greater than a preset value;
if the counter value is less than or equal to the preset value, determine whether the actual efficiency is less than the efficiency threshold again; and
if the counter value is greater than the preset value, determine that the aging level of the power supply system exceeds a preset level.

23. The power supply system according to claim 22, wherein the primary control unit is further configured to issue an alert signal to warn a user when the aging level of the power supply system exceeds the preset level.

24. The power supply system according to claim 18, wherein the primary control unit is configured to:
if the actual efficiency is less than the efficiency threshold, determine that the power supply system has aged; and
if the actual efficiency is greater than or equal to the efficiency threshold, determine that the power supply system has not aged.

25. The power supply system according to claim 16, wherein the digital opto-isolation coupler comprises a plurality of opto-isolators, each of which is configured to transmit one-bit signal, and the PWM signal from the secondary control unit is transmitted to the primary control unit through one of the plurality of opto-isolators.

26. The power supply system according to claim 16, wherein the first conversion circuit comprises a PFC (power factor correction) circuit with a PFC output capacitor, the primary electrical parameter comprises a reference capacitance of the PFC output capacitor, the secondary electrical parameter comprises an output power or an output current of the second conversion circuit, the aging reference parameter comprises an actual ripple voltage of the PFC output capacitor, and the parameter threshold comprises a ripple voltage threshold of the PFC output capacitor; wherein the primary control unit is configured to calculate the ripple voltage threshold according to the secondary electrical parameter and the reference capacitance, obtain the actual ripple voltage, and compare the actual ripple voltage with the ripple voltage threshold to determine an aging level of PFC output capacitor of the power supply system.

27. The power supply system according to claim 26, wherein the ripple voltage threshold of the PFC output capacitor is calculated as:
$$Vth = \frac{Ip}{2 * π * {f}_{line} * C ref}$$
where Vth is the ripple voltage threshold, Ip is the output current of the PFC circuit obtained by the primary control unit according to the secondary electrical parameter, fₗᵢₙₑ is a line frequency, and Cref is the reference capacitance of the PFC output capacitor.

28. The power supply system according to claim 26, wherein the primary control unit is configured to:
set threshold values based on the ripple voltage threshold; and
compare the actual ripple voltage with the threshold values to determine the aging level of the PFC output capacitor.

29. The power supply system according to claim 26, wherein the primary control unit is configured to determine that the PFC output capacitor has aged when at least one of conditions is satisfied, and the conditions comprises that a peak value of the actual ripple voltage is greater than an upper limit of the ripple voltage threshold, a valley value of the actual ripple voltage is less than a lower limit of the ripple voltage threshold, and a peak-to-peak value of the actual ripple voltage is greater than a peak-to-peak limit of the ripple voltage threshold.

30. The power supply system according to claim 16, wherein the secondary electrical parameter comprises multi-bit information, the secondary control unit is configured to provide the PWM signal with different frequencies, different duty cycles, or different combinations of frequency and duty cycle to represent the multi-bit information, and the primary control unit is configured to obtain the multi-bit information of the secondary electrical parameter reflected by the PWM signal according to the frequency and the duty cycle of the PWM signal.
